(19) United States
(12) Patent Application Publication
(10) Pub. No.: US 2011/0241063 A1
(43) Pub. Date: Oct. 6, 2011

(54) MULTILAYER DEVICES ON FLEXIBLE SUPPORTS

(76) Inventor: Christopher John Winscom, Histon (GB)

(21) Appl. No.: 13/132,326

(22) PCT Filed: Dec. 22, 2009
(86) PCT No.: PCT/US09/06671

§ 371 Date: Jun. 2, 2011

(30) Foreign Application Priority Data
Dec. 23, 2008 (GB) 08233975

(51) Int. Cl. H01L 33/62; H01L 33/02; B32B 7/02

(52) U.S. Cl. 257/99; 257/103; 428/213; 257/E33.013; 257/E33.064

(57) ABSTRACT

A flexible element has a flexible support comprising two or more layers with different modulus of elasticities in bound contact with each other, and at least one thin film wherein the total thickness of the thin film(s) is less than the total thickness of the flexible support at any point of contact between the support and the thin film(s); and at least one thin film is deposited on the outer surface of the layer of the flexible support having the higher elastic modulus.

### FIELD OF THE INVENTION

This invention relates to a flexible support, consisting of a flexible plastic on glass composition, which lessens the mechanical stress in all thin layers on the support, particularly the brittle and sensitive components of a thin multilayer, preferably an OLED device, and particularly during deposition of successive thin layers in a roll-to-roll process.

### BACKGROUND OF THE INVENTION

Thin multilayer devices, exemplified by a traditional OLED device, and in particular the electrodes and organic layers located therein, are susceptible to degradation resulting from interaction with oxygen and moisture leaking into the device from the ambient environment. The life of an OLED display, for example, can be increased significantly if the electrodes and organic layers within the OLED display are protected from moisture and oxygen, which may destroy them if they reach the thin active layers. For instance, supports, encapsulants and hermetic seals should provide a barrier for oxygen (10⁻³ cc/m²/day) and water (10⁻⁶ g/m²/day).

Glass is one of the few materials simultaneously offering transparency, a scalable surface, and an efficient, long term barrier to oxygen and moisture. These properties are required for current display panels, on at least one side of the device. As such, glass remains a prime candidate for OLED display manufacture. For instance, rigid OLED displays may use sheets of glass to encase the OLED pixels, which then may be hermetically sealed using a frit seal among other methods.

Supports consisting solely of glass may act as an effective barrier to moisture and oxygen, but inevitably must also be thick enough to provide the physical robustness to support the area of the display as a whole. This makes the support not only rigid, but also imparts a significant weight/unit area of a display. Rigidity excludes roll-to-roll device fabrication processes thus adding cost to manufacture, and the disproportionate weight also adds cost to distribution and installation. It is desirable therefore to seek lightweight, flexible alternatives.

Polymeric substrates, as alternative lightweight and flexible supports, are particularly susceptible to permeation of moisture and oxygen. Attempts have been made (Graf et al in “Flexible Flat Panel Displays” Ed. G. P. Crawford, John Wiley, Chichester (2005), Ch. 4, pp 57-77) to reduce rates of ingress of oxygen and moisture by incorporating one or more thin alternating layers of typically SiOₓ and polymer, respectively, as a barrier. The individual thicknesses of such component layers are typically in the range 10-100 nm. This preserves the lightweight, flexible and transparent characteristics of the support, but has the disadvantage that the protection achieved does not reach that of a single thicker glass layer in the thickness range of 10 μm or more. However, use of a single glass layer with a thickness of 10 μm or more, requires the mechanical effects of strain be considered. Strain is defined as the relative elongation or compression in a given direction, in response to a force acting on the material. It is generally expressed as a percentage. The stress within a material is directly proportional to the strain, the constant of proportionality being the modulus of elasticity, known as Young's Modulus, generally expressed in units of GPa (Giga Pascals). Materials are characterised by certain limiting stresses, or strains. For example, the breaking stress or breaking strain is a limit above which the material breaks apart. The fracture stress or strain is the limit above which surface fractures propagate uncontrollably. Yield strength (in GPa) is also used in a similar context and is the limit beyond which material deformation is irreversible. Materials are often referred to as brittle when they have a higher modulus of elasticity of 50 GPa or more, and have a breaking strain of 2% or less.

The flexibility of an individual glass layer can be characterized by its radius of curvature. This occurs when a bending moment is applied, for example in roll-to-roll manufacturing processes, and other practical flexible attributes of devices where radii of curvature in the range from 10 mm to 10 cm are involved (see for example, Gregg et al in “Flexible Flat Panel Displays” Ed. G. P. Crawford, John Wiley, Chichester (2005), Ch. 21, pp 409-445, and references therein).

The strain at any location in the material is proportional to the curvature, which is equal to the reciprocal of the radius of curvature. Glass thicknesses compatible with such radii at an admissible level of stress throughout the thickness of the material along the radial direction, are in the range of 10 to 30 μm. Producing such thin glass sheet is still an exacting task using known techniques.

WO 2005/110741 discloses a process for the production of ultra thin glass having a thickness as low as 5 μm. A polymer coating is applied to the glass in a thickness 50 μm, and assorted polymer compositions have been disclosed and tested. Various tests related to mechanical flexibility, oxygen permeability, moisture permeability, puncture resistance, and polymer-to-glass adhesion have been performed on the composite layered material comprising the thin glass and polymer coating to investigate its suitability for use in OLED displays, lighting, and other applications. WO 2008/093153 also discloses methods relating to drawing and blowing of ultra thin glass substrates, which may be bonded to polymer substrates, such as flexible display glass sheets for use in organic light emitting diode (OLED) displays. The prospects of flexible glass of thicknesses in the range 10-100 μm bound to a thicker polymeric layer are within manufacturable reach.

In many electronic devices, inorganic materials typically used as conductors, such as transparent conductive oxides, or semiconductors, such as amorphous silicon and silicon nitride, are brittle and crack easily when substrates are deformed. In general, inorganic materials are more brittle and crack more easily than organic materials, at least in the context of materials commonly used to fabricate organic electronic devices. Many of the component layers in OLED devices are organic in nature and are less prone to this problem. Nevertheless, it is generally intended to emit light through at least one of the electrodes, and one or more transparent electrodes may be useful in such organic opto-electronic devices. For example, a transparent electrode material, such as indium tin oxide (ITO), may be used as the bottom electrode. Sputtered ITO films have been conventionally applied to devices that employ transparent conductors. However, the ITO films are limited in their applications due to their brittleness and low tolerance to stress. Even minute fractures in an ITO film can cause a rapid loss of conductivity and a disadvantageous increase in its sheet resistance. This becomes critical in current-driven devices such as OLEDs. ITO is a preferred transparent conductive inorganic material, but it has a Young's modulus of 120 GPa and a yield strength of only 1.2 GPa. Very rapid sheet resistance changes are observed to occur for strains as defined above of 2% or more, which equate to stresses of 2.4 GPa or more. Some insulating materials that may be desirable in certain types of organic devices such as thin film transistors may have fracture strains as low as 0.05% (MgO, for example). It is believed that most practical applications of multilayer devices will involve higher radial or biaxial strains, such as 1.5% and above. To achieve flexible electronics, it is desirable to mitigate the effects of stress caused by an applied mechanical strain in such device structures on deformable substrates.

Much of the work to date (see e.g. Bouten et al in “Flexible Flat Panel Displays” Ed. G. P. Crawford, John Wiley, Chichester (2005), Ch. 6, pp 99-120) on thin foil substrates considers the uniaxial strains encountered in cylindrical bending deformation, as might be experienced in a roll-to-roll manufacturing process. In such cases, the semiconductor films on the inside of the deformed surface are in compression and those on the outside are in tension. There exists an intermediate elemental layer between these inner and outer surfaces which experiences no stress—this is commonly referred to as the neutral plane or neutral layer. Assuming the multilayer film thickness is negligible compared to the substrate and the neutral plane lies at the middle of the substrate cross-section, the magnitude of stress (σᵢ) in any very thin layer (i) deposited on either of the outer surfaces of the substrate is given by:

σᵢ=½Eᵢt/R (1)

where t is the substrate thickness and R is the radius of curvature.

US 2003/0213956 describes devices within an active matrix display intended to have flexibility and strength by first forming active elements on a thick glass substrate serving as a device forming substrate and then making the glass substrate thinner, and finally bonding the glass substrate to a flexible supporting substrate, such as a plastic substrate via an adhesion layer. It recognises that the surface stress can be decreased by reducing the substrate thickness, and tighter radii of curvature can be achieved simply by using thinner substrates. However, deposition on an initially thick substrate, however, would preclude a roll-to-roll deposition process.

US 2007/0105252 describes a method of manufacturing a flexible device where glass is used as a mother substrate and a polymer layer is used as a substrate formed on the mother substrate, and a device is formed on the polymer substrate. An over-layered encapsulation of the same polymer is applied before the polymer-enclosed device is separated from the mother substrate to produce an unimpaired flexible device. However, after separation from the mother substrate, the stress in a brittle thin layer of the device is not necessarily relieved. US 2006/0169989 describes brittle layers in devices being unexpectedly much more resistant to fracture when an organic over-layer is present. It is believed that the organic layer may act to suppress crack formation by providing a compressive stress wherever a crack seeks to nucleate or propagate. Fractures may be protected against, but the inherent stress within the brittle layer is not relieved.

J-I Han in “Flexible Flat Panel Displays” Ed. G. P. Crawford, John Wiley, Chichester (2005), Ch. 7, pp 121-133 discloses strain relief in ITO layers using a polymer substrate with a buffer layer of lower modulus of elasticity.

WO 2004/086530 describes enclosing a thin layer device containing a brittle layer between a first and second substrate, such that the neutral layer lies in, or very near to the device layers. The layer order of typical structure would be an aluminium support, the thin layers of the device, a flexible glass layer and a PET layer.

US 2006/0132025 describes the technique of strain balancing, wherein it was shown that a neutral layer position could be achieved but was still located in the support layer. The problem was solved by simply adding an additional balancing layer on top of the second substrate. The art cites the need to relieve strain during the manufacture of a flexible display using a roll coating machine. This may require transport over and around rollers with diameters as small as a few centimeters. However, strain protection in the thin multilayer device will only be afforded to the finished OLED device. Whilst this reference has attempted to address the problem, protection of the device layers during the process of being sequentially deposited in a roll-to-roll situation is required when the second substrate and balancing layers are not yet present.

US 2006/0132698 describes a symmetrical arrangement of the first and second substrate sandwiching the thin multilayer device, employed to lessen thermal deformation. The ordering in the arrangement is: (PET, flexible glass), (device layers), (flexible glass, PET). This arrangement is typically 1000 μm PET and 60 μm flexible glass.

In summary, there are situations where it is not practical to reduce the overall thickness of the support, or rely solely on fracture protection, in an effort to preserve the integrity of particularly the more brittle, but crucial, thin layers, such as ITO in a multilayer device. For example, during the sequential deposition process, strain balancing overlayers must be necessarily absent. The combination of PET and flexible glass as a composite substrate is also known for relief of thermal deformation.

### SUMMARY OF THE INVENTION

The invention provides for a composite substrate that minimises strain in all layers of a thin multilayer particularly during the sequential deposition of the layers in a roll-to-roll process.

According to the present invention there is provided a flexible element comprising a flexible support comprising two or more layers with different modulus of elasticities in bound contact with each other, at least one thin film wherein the total thickness of the thin film(s) is less than the total thickness of the flexible support at any point of contact between the support and the thin film(s); and where the at least one thin film is deposited on the outer surface of the layer of the flexible support having the higher elastic modulus.

### ADVANTAGEOUS EFFECT OF THE INVENTION

The stress in the thin layers of an element in accordance with the invention is significantly reduced, whilst maintaining an overall thickness of support, and the flexibility and transparency of the substrate. It also allows incorporation of a glass component in the support as an effective barrier to oxygen and moisture.

### BRIEF DESCRIPTION OF THE DRAWINGS

The invention will now be described by way of example with reference to the following drawings in which:

FIG. 1 is a graph illustrating stress in a thin (100 nm) ITO layer deposited on a PET/flexible glass composite support of 175 μm total thickness, for a bend radius of 1.2 cm; the yield strength of ITO is shown for comparison;

FIG. 2 is a graph illustrating stress in a thin (100 nm) ITO layer deposited on the glass surface, the stress in the uppermost surface region of the glass layer onto which the ITO is deposited, and the flexible glass break stress for a PET/flexible glass composite support of 175 μm total thickness, for a bend radius of 1.2 cm;

FIG. 3 is a graph illustrating stress in a thin (100 nm) ITO layer deposited on the glass surface, the stress in the uppermost region of the glass layer onto which the ITO is deposited, and the flexible glass break stress for a PET/flexible glass composite support of 125 μm total thickness, for a bend radius of 1.2 cm;

FIG. 4 is a graph illustrating the effect of an additional chromium layer to a PET/glass support and showing the stress in the middle glass layer in the region of the glass-chromium interface, the stress in the chromium layer in the region of its interface with ITO, and the stress in the thin ITO layer; the PET layer is 100 μm thick and the total glass plus chromium thickness is 25 μm; and

FIG. 5 is a graph illustrating the effect of an additional chromium layer to a PET/glass support and showing the stress in the middle glass layer in the region of the glass-chromium interface, the stress in the chromium layer in the region of its interface with ITO, and the stress in the thin ITO layer; the PET layer is 100 μm thick and the total glass plus chromium thickness is 15 μm.

### DETAILED DESCRIPTION OF THE INVENTION

The modulus of elasticity is a ratio of an increment of stress to an increment of strain. For the present invention the modulus of elasticity is the Young's modulus where at low strains the relationship between stress and strain is linear, such that a material can recover from stress and strain. The modulus of elasticity may also be referred to as coefficient of elasticity, elasticity modulus, or elastic modulus. The modulus of elasticity is a mechanical property well known to those of ordinary skill. A description of the modulus of elasticity and other mechanical properties of materials, and analysis thereof, can be found in Marks' Standard Handbook for Mechanical Engineers, eds. Avalone, E. and Baumeister III, T., 9^{th} edition, Chapter 5, McGraw Hill, 1987. In a thin multilayer stack of different materials deposited on a much thicker substrate, the stress experienced by any of the thin layers is proportional to its distance from the neutral plane. The position of the neutral plane in any cross-section of a thick homogeneous substrate is at the cross-section's mid-point. By making the substrate non-homogeneous, as in the case represented by the simplest embodiment, a two-layer composition of, for example, a polymeric material and glass, the position of the neutral layer can be significantly shifted from the cross-section mid-point to lie nearer the outer surface of the component having the higher modulus of elasticity. Glass is taken to mean an inorganic material selected from the group consisting of silicon oxide based glasses. Suitable silicon oxides are, for example, borosilicate and aluminosilicate glasses.

In fact, it will be shown that the component of higher elasticity need occupy only a relatively smaller fraction of the total thickness, to have the optimum effect. By imposing a given radius of curvature on such an arrangement, thereby causing internal strain, there are two important consequences. Firstly, the stress in any individual layer in the thin multilayer stack of the device, deposited on the surface of a higher elasticity, minority thickness component of the substrate, is always reduced relative to the same strain conditions in a homogeneous substrate of either the lower, or the higher elasticity component on its own. Conversely, deposition of the thin multilayer on the surface of the low elasticity majority thickness component results in increased stress. Secondly, the extent of the reduction relative to using a homogeneous substrate is dependent on the overall absolute thickness of the composite substrate, the relative thickness proportions of the at least two components, and the relative elasticities of those components.

The thin films coated on the flexible support of the invention can be a multilayer OLED device consisting of a number of organic layers of thicknesses individually in the range of 1-100 nm enclosed by a transparent conductive anode and a low work function metallic cathode whose thicknesses are typically less than or equal to 100 nm. The total thickness of the OLED device is less than 1 μm and preferably less than 500 nm, most preferably less than 250 nm. It is highly desirable that the transparent current carrying anode of the OLED device be in direct contact with the outer surface of the layer with the highest modulus of elasticity.

However, the thin film(s) can be located on the outer surface of either layer of the flexible support. This means that the thin films are in direct contact with the layer with the lowest modulus of elasticity or in direct contact with the layer with the highest modulus of elasticity. It is preferred that the thin film(s) are located on the outer surface of the layer with the highest modulus of elasticity.

Assuming that the multilayer device (typically<<1 μm) is much thinner than a conventional support substrate (typically>100 μm), the position of the neutral plane in a two layer substrate is determined to a good approximation by equating the net force acting on the neutral plane under bending to zero. Hence:

$$0 = \frac{{E}_{s}}{R} {\int }_{0}^{{h}_{s}} w ( y - c ) d y + \frac{{E}_{a}}{R} {\int }_{{h}_{s}}^{{h}_{s} + {h}_{a}} w ( y - c ) d y \qquad ( 2 )$$

where R is the radius of curvature imposed on the support and device, Eₛ, Eₐ are the moduli of elasticity, and hₛ, hₐ are the layer thicknesses of the lower layer (s) and upper additional layer (a) of the support, respectively, w is the cross-sectional width of the coating, y is the distance from the outer surface of the lower layer, s, to an arbitrary height in the cross-section, and c is the distance of the neutral layer from the outer surface of the lower layer. The position of the neutral layer is then given by:

c=½.(Eₛhₛ²+Eₐhₐ²+2Eₐhₛhₐ)/(Eₛhₛ+Eₐhₐ) (3)

and is seen to be independent of the radius of curvature. Under the assumption that the multilayer device is very much thinner than the composite supporting substrate, the stress, σᵢ, in any individual thin layer within a device deposited at the surface of the minority thickness higher elasticity component is accurately given by:

σᵢ=Eᵢ(hₛ+hₐ−c)/R (4)

where Eᵢ is the modulus of elasticity of an arbitrary component in the thin multilayer device.

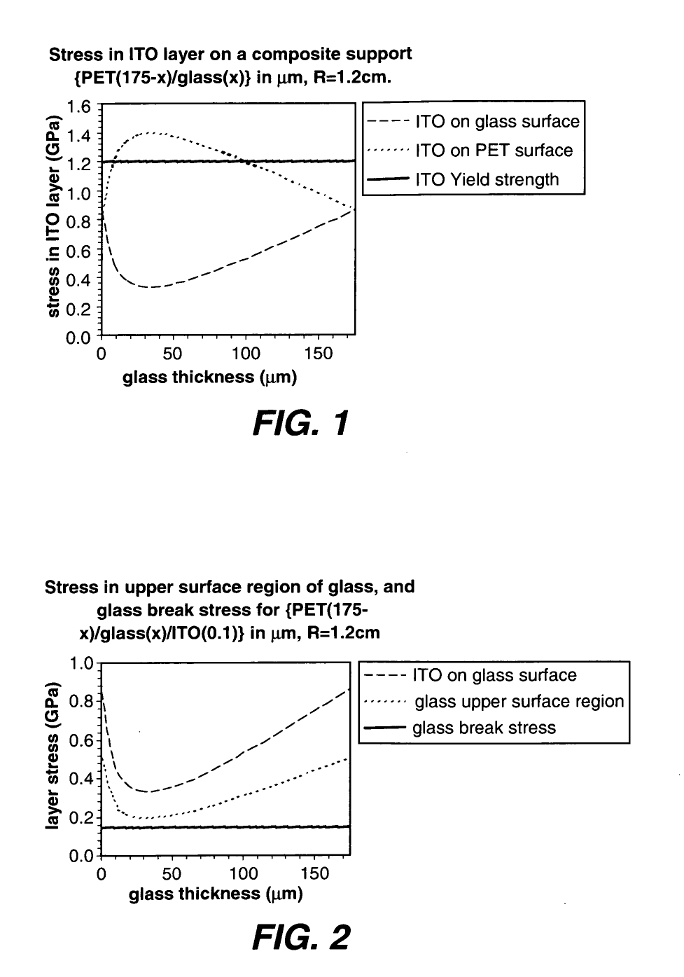

FIG. 1 show curves representing the stress in a thin (100 nm) ITO layer for the two possible simple three-layer arrangements of constant total thickness, T=175 μm: {(PET (T-x)/glass (x)/ITO(100 nm)} and {glass (x)/PET (T-x)/ITO(100 nm)} (these are also the generic formula for FIGS. 1, 2 and 3) having a 1.2 cm radius of curvature imposed upon them. The dotted line indicates for the yield strength of the ITO for comparison. Clearly, the choices for avoiding ITO fracture can be determined.

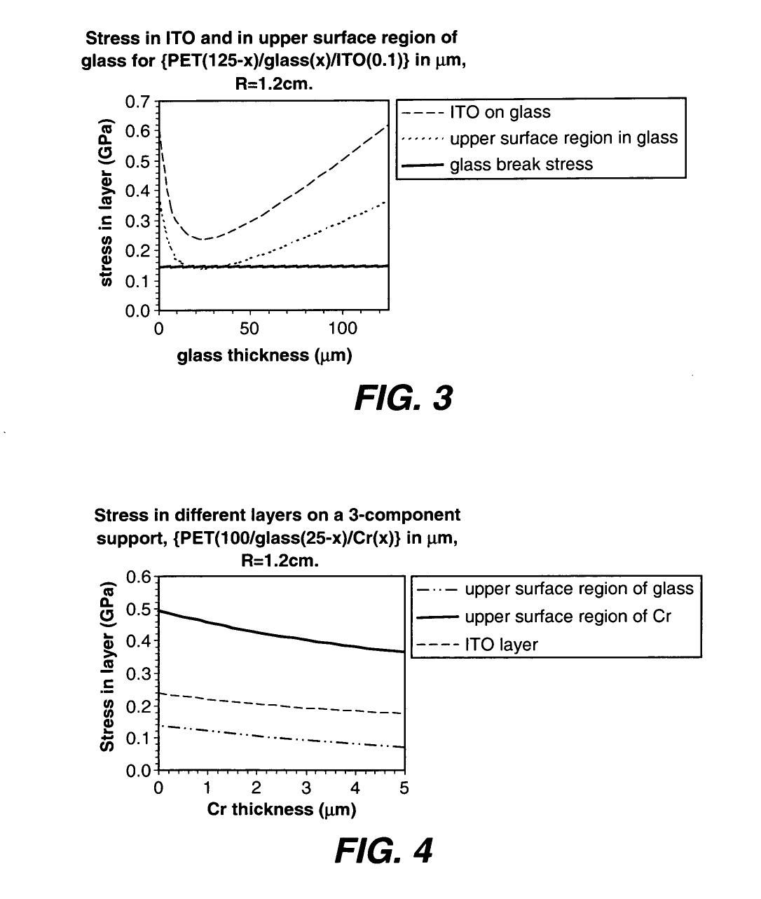

FIG. 2 is a graph illustrating stress in a thin (100 nm) ITO layer deposited on the glass surface, and the stress in the uppermost surface region of the glass layer onto which the ITO is deposited, and the flexible glass break stress for a PET/flexible glass composite support of 175 μm total thickness, for a bend radius of 1.2 cm. FIG. 3 is a graph illustrating stress in a thin (100 nm) ITO layer deposited on the glass surface, and the stress in the uppermost region of the glass layer onto which the ITO is deposited, and the flexible glass break stress for a PET/flexible glass composite support of 125 μm total thickness, for a bend radius of 1.2 cm. Clearly, a reduction of the overall thickness of the composite from 175 μm to 125 μm, whilst maintaining the thickness proportions, can relieve the stress in the glass layer to avoid breakage, and further lower the stress in the ITO layer.

In embodiments which involve three layers of different materials, equation 3 becomes:

c=½.(Eₛhₛ²+Eₐhₐ²+2Eₐhₛhₐ+E_{b}h_{b}²+2E_{b}h_{b}(hₛ+hₐ))/(Eₛhₛ+Eₐhₐ+E_{b}h_{b}) (5)

where b labels the third support component layer located on the second layer. By extension, a general expression for more than 3 layers may be derived. Inspection shows that no advantage is gained if the support layer architecture has a cross-section which is symmetric in component thicknesses and elasticities about its centre, since c then lies at the midpoint as in the single homogeneous substrate case. Advantageous stress relief in the thin multilayer device is obtained when the layer ordering is asymmetric, and the thin multilayer device is deposited on the surface to which the neutral plane is nearest. Furthermore, it is useful to consider additional metal components in the composite support to provide extra strain relief in both the thin multilayer device above it and the layer of lower modulus, e.g. glass, below it whilst acting as an underlying mirror or conductor. Such metals, e.g. chromium, must bind well to e.g. glass, as the underlying layer in the support, and must have a coefficient of linear thermal expansion, not dissimilar to that of glass (3.3 to 8.5 ppm ° C.⁻¹) (e.g. Be, Cr, W, Os are all in the range 4.5-6.5 ppm ° C.⁻¹), a modulus of elasticity greater or equal to that of glass (65-90 GPa), and exhibit some affinity to bind well to glass by, e.g. forming an intermediate oxide at the glass metal interface.

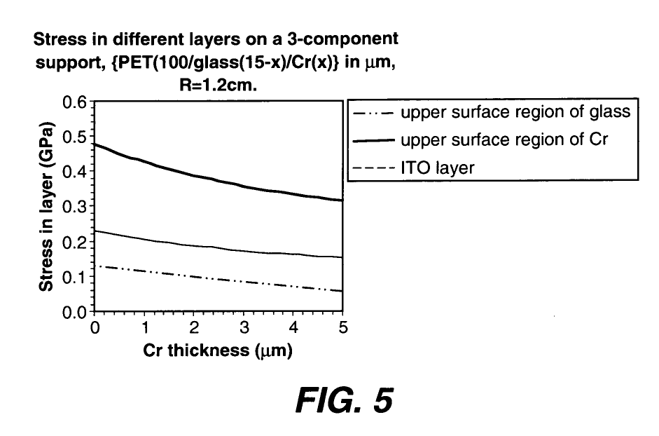

FIG. 4 is a graph illustrating the effect of an additional chromium layer to a PET/glass support; and showing the stress in the middle glass layer in the region of the glass-chromium interface, the stress in the chromium layer in the region of its interface with ITO, and the stress in the thin ITO layer. The PET layer is 100 μm thick and the total glass plus chromium thickness is 25 μm. FIG. 5 is a graph illustrating the effect of an additional chromium layer to a PET/glass support; and showing the stress in the middle glass layer in the region of the glass-chromium interface, the stress in the chromium layer in the region of its interface with ITO, and the stress in the thin ITO layer. The PET layer is 100 μm thick and the total glass plus chromium thickness is 15 μm. FIGS. 4 and 5 show the performance of an asymmetric three-layer support in which the stress of a thin layer of ITO in a multilayer device is plotted against thickness proportion of a {PET/glass/chromium/thin multilayer incl. ITO}

Chromium has a Young's modulus of 248 GPa, and a breaking stress of 0.41 GPa. Devices often require a metal electrode at the bottom of a multilayer device, but need an intermediate chromium layer as binder to glass. The large modulus of elasticity of chromium means that as third layer in the support composite, of reduced thickness, brings yet a further advantage to the much thinner layers of the device. Comparing a {PET(100 μm)/glass(25 μm)} with the 3-layer composite {PET(100 μm)/glass(25-x μm)/Cr(x μm)} for a range x=0 to 5 μm having the same total thickness (see table 2) the stress in any layer of a thin multilayer device deposited on the chromium surface is further reduced by 25%.

For a support consisting of two layers the polymer layer should have a modulus of less than or equal to 8 GPa and a second layer should have a modulus greater than 8 GPa. The relative thicknesses of the two layers, respectively, are in the range of 2:1 to 20:1, preferably in the range of 2.5:1 to 15:1. Desirably the polymer layer should have a thickness in the range of 75-150 μm, preferably between 100-140 μm, while the thickness of the glass layer should desirably have a thickness in the range of 10-50 μm, preferably between 10-30 μm.

For a three layer support the polymer layer should have a modulus of less than or equal to 8 GPa, a second layer should have a modulus greater than or equal to the first layer, and a third layer should have a modulus greater than or equal to the second layer. The relative thicknesses of the first layer to the sum of the second and third layer is in the range 2:1 to 20:1, and the third to the second layer thicknesses, respectively, is from 0:1 to 1:1. This third layer should have a thickness in the range of 0.5-10 μm, preferably between 3-7 μm.

In any case, the total combined thickness of the flexible support should be 500 μm or less, preferably in the range of 100-250 μm.

Typically, the flexible layer can be made of polyethylene terephthalate (PET), polyethylene naphthalate (PEN), polyethersulfone (PES), polycarbonate (PC), polysulfone, a phenolic resin, an epoxy resin, polyester, polyimide, polyetherester, polyetheramide, cellulose acetate, aliphatic polyurethanes, polyacrylonitrile, polytetrafluoroethylenes, polyvinylidene fluorides, poly(methyl (x-methacrylates), an aliphatic or cyclic polyolefin, polyarylate (PAR), polyetherimide (PEI), polyethersulphone (PES), polyimide (PI), Teflon poly(perfluoro-alboxy) fluoropolymer (PFA), poly(ether ether ketone) (PEEK), poly(ether ketone) (PEK), poly(ethylene tetrafluoroethylene)fluoropolymer (PETFE), and poly(methyl methacrylate) and various acrylate/methacrylate copolymers (PMMA). Aliphatic polyolefins may include high density polyethylene (HDPE), low density polyethylene (LDPE), and polypropylene, including oriented polypropylene (OPP). Cyclic polyolefins may include poly(bis(cyclopentadiene)). A preferred flexible plastic substrate is a cyclic polyolefin or a polyester, particularly PET. Various cyclic polyolefins are suitable for the flexible plastic substrate. Examples include Arton® made by Japan Synthetic Rubber Co., Tokyo, Japan; Zeanor T made by Zeon Chemicals L.P., Tokyo Japan; and Topas® made by Celanese A. G., Kronberg Germany. Arton is a poly(bis(cyclopentadiene)) condensate that is a film of a polymer. Alternatively, the flexible plastic substrate can be a polyester. A preferred polyester is an aromatic polyester such as Arylite.

### Example 1

A composite support comprising two layers: PET and flexible glass, having a constant total thickness of 175 μm is subjected to applied stress with a tight bending radius of 1.2 cm. The stress in a thin ITO layer deposited on one, or the other, of the two surfaces of the support, can be simulated. The result is shown in FIG. 1, in comparison to the yield strength of ITO. In the case of ITO deposited on the PET surface, all proportions cause an increase in stress in the ITO over the 100% glass, or 100% PET, compositions. In the region around the maximum, the yield strength of ITO is exceeded. On the other hand, if ITO is deposited on the glass surface, there is a clear minimum of stress for the same proportions. Clearly, it is preferable to deposit ITO on the glass surface to protect the ITO integrity. These results are summarised in Table 1.

TABLE 1
Calculated stress in a thin ITO layer on different PET/glass support compositions
for a radius of curvature of 1.2 cm. The moduli of elasticity for PET,
glass, and ITO were 4 GPa, 65 GPa and 120 GPa, respectively.

| | | Calculated | Calculated |
|---|---|---|---|
| | | Stress in | maximum |
| | | thin ITO | stress in the |
| Sample | Composition | layer (GPa) | glass (Gpa) |
| 1a Comparison | PET (175 μm)/ITO (100 nm) | 0.81 | — |
| 1b Comparison | Glass (175 μm)/ITO (100 nm) | 0.81 | |
| 1c Comparison | Glass (35 μm)/PET (140 μm)/ITO | 1.41 | |
| | (100 nm) | | |
| 1d Invention | PET (140 μm)/Glass (35 μm)/ITO | 0.33 | 0.19 |
| | (100 nm) | | |
| 1e Comparison | PET (125 μm)/ITO (100 nm) | 0.61 | — |
| 1f Comparison | PET (125 μm)/ITO (100 nm) | 0.61 | — |
| 1g Invention | PET (100 μm)/Glass (25 μm)/ITO | 0.28 | 0.14 |
| | (100 nm) | | |

Table 1 also includes the results from FIGS. 2 and 3 which shows the stresses involved in the ITO layer, and the upper surface region of the glass layer. The glass likewise experiences a minimum stress for the same proportions, but for an overall support thickness of 175 μm, the optimum position is close to the break stress of the glass. This can be accommodated by reducing the overall thickness of the support to 125 μm, as shown in FIG. 3.

The important general result for ITO, as one component in a thin multilayer device, is that to obtain any stress relief, the thin multilayer must be coated on the outer surface of the composite support belonging to the layer having the larger Young's modulus. All simulations have been carried out under conditions of tight bending radii typical of the smallest met in a roll-to-roll manufacturing process.

### Example 2

In this series, a composite support comprising 3 layers: {PET/flexible glass/chromium} of total thickness 125 μm, the layer ordering shown, and subjected to a bend radius of 1.2 cm. Chromium has a Young's modulus value of 248 GPa, and a breaking stress of 0.41 GPa. FIG. 4 shows the effect of an additional chromium layer to the support on the ITO stress, and in the regions of highest stress in the glass and chromium layers of the substrate. The starting position (Cr=0 μm) approximates closely to the optimum position in shown in FIG. 3. As the proportion of the chromium is increased at the expense of the flexible glass layer, the stresses in the three regions: the upper surface region of the glass nearest glass/Cr interface, the upper surface region of the Cr nearest the Cr/thin multilayer interface, and the thin ITO layer, are all reduced. However, the introduction of chromium requires that the breaking stress of this material (0.41 GPa) is not exceeded—in this example a layer of at least 2 μm is required. This limiting thickness may be effectively reduced to 1 μm, by reducing the glass plus chromium thickness proportions as shown in FIG. 5. Table 2 summarises the calculated stress for different samples to demonstrate those advantaged by stress relief.

TABLE 2
Calculated stress in a thin ITO layer on different PET/glass/chromium support compositions
for a radius of curvature of 1.2 cm. The moduli of elasticity for PET, glass, chromium
and ITO were 4 GPa, 65 GPa, 248 GPa and 120 GPa, respectively.

| | | Calculated | Calculated | Calculated |
|---|---|---|---|---|
| | | Stress in | maximum | maximum |
| | | thin ITO | stress in the | stress in the |
| Sample | Composition | layer (GPa) | glass (Gpa) | Cr (Gpa) |
| 1a Comparison | PET (175 μm)/ITO (100 nm) | 0.81 | — | — |
| 1d Comparison | PET (140 μm)/Glass (35 μm)/ITO | 0.33 | 0.19 | — |
| | (100 nm) | | | |
| 1g Comparison | PET (100 μm)/Glass (25 μm)/ITO | 0.24 | 0.14 | — |
| | (100 nm) | | | |
| 2a Invention | PET (100 μm)/Glass (20 μm)/Cr | 0.18 | 0.08 | 0.36 |
| | (5 μm)/ITO (100 nm) | | | |
| 2b Comparison | PET (100 μm)/Glass (15 μm)/ITO | 0.23 | 0.13 | — |
| | (100 nm) | | | |
| 2c Invention | PET (100 μm)/Glass (10 μm)/Cr (5 | 0.16 | 0.06 | 0.32 |
| | μm)/ITO (100 nm) | | | |

The series of samples for example 2 describes the use of an additional chromium layer in the support. Other suitable metals include aluminium, beryllium, iron, tungsten, ruthenium, osmium, palladium, platinum, or other metals having a coefficient of linear thermal expansion preferably in the range 3-9 ppm ° C.⁻¹, and known to bind to glass. It is clear from samples 2a and 2c, that substrate compositions can be designed where the stress in the ITO layer is further reduced to 66%-75% compared with 1 g, the maximum stress in the glass layer is approximately halved, and lies substantially under its breaking stress of 0.15 GPa for 30 μm flexible glass, and the maximum chromium stress lies under its breaking stress of 0.41 GPa.

1. A flexible element comprising:
a) a flexible support comprising two or more layers with different modulus of elasticities in bound contact with each other, and
b) at least one thin film wherein the total thickness of the thin film(s) is less than the total thickness of the flexible support at any point of contact between the support and the thin film(s); and
c) where the at least one thin film are deposited on the outer surface of the layer of the flexible support having the higher elastic modulus.

2. A flexible element according to claim 1, the flexible support comprising two layers, a first layer consisting of a polymer with a modulus of elasticity of less than or equal to 8 GPa and a second layer having modulus of elasticity greater than 8 GPa, and the relative thicknesses of the two layers, respectively, being in the range of 2:1 to 20:1, the total combined thickness of the flexible support being 500 μm or less.

3. A flexible element according to claim 1 wherein the flexible support consists of three layers, a first polymer layer having a modulus of elasticity of less than or equal to 8 GPa, a second layer having a modulus of elasticity greater than or equal to the first layer, and a third layer having a modulus of elasticity greater than or equal to the second layer, wherein the relative thicknesses of the first layer to the sum of the second and third layer are in the range 2:1 to 20:1, and the third to the second layer thicknesses, respectively, is from 0:1 to 1:1.

4. A flexible element according to claim 2, wherein the second layer of the support is an inorganic silicon oxide based glass material.

5. A flexible element according to claim 3, wherein the third layer of the support is chosen from chromium, aluminium, beryllium, iron, tungsten, ruthenium, osmium, palladium, platinum, or other metal having a coefficient of linear thermal expansion in the range 5-25 ppm ° C.⁻¹, and known to bind to glass.

6. A flexible element according to claim 1 wherein at least one of the one or more thin films constitute an organic light emitting device.

7. A flexible element according to claim 6 wherein the OLED thin films include at least one brittle current-carrying transparent conducting oxide layer, or at least one brittle dielectric insulator layer, or at least one brittle semiconductor layer.

8. A flexible element according to claim 7, in which the OLED thin films constitutes an electroluminescent device incorporating at least one current carrying transparent conductive oxide layer.

9. A flexible element according to claim 8, in which a current carrying transparent conductive oxide layer of the organic light emitting device is located on the outer surface of the layer with the highest modulus of elasticity.
